(19) United States
(12) Patent Application Publication
(10) Pub. No.: US 2020/0235067 A1
(43) Pub. Date: Jul. 23, 2020

(54) ELECTRONIC DEVICE FLIP CHIP PACKAGE WITH EXPOSED CLIP

(71) Applicant: Texas Instruments Incorporated, Dallas, TX (US)

(72) Inventors: Woochan Kim, Sunnyvale, CA (US); Dibyajat Mishra, Fremont, CA (US); Kurt Sincerbox, San Jose, CA (US); Vivek Arora, San Jose, CA (US)

(73) Assignee: Texas Instruments Incorporated, Dallas, TX (US)

(21) Appl. No.: 16/253,680

(22) Filed: Jan. 22, 2019

(51) Int. Cl. H01L 23/00; H01L 23/538; H01L 23/31; H01L 25/07; H01L 25/00

(52) U.S. Cl. CPC H01L 24/40; H01L 23/552; H01L 24/16; H01L 23/3121; H01L 25/072; H01L 24/81; H01L 24/84; H01L 25/50; H01L 24/73; H01L 24/92; H01L 23/5386; H01L 2224/73255; H01L 2224/92226; H01L 2224/81815; H01L 2224/84801; H01L 2224/40225; H01L 2224/16227; H01L 2224/13147; H01L 24/13; H01L 2224/37124; H01L 2224/37147; H01L 24/37; H01L 23/5383

(57) ABSTRACT

A packaged electronic device includes a multilayer substrate, including a first side, a first layer having a first plurality of conductive structures along the first side, and a second layer having a second plurality of conductive structures, a semiconductor die soldered to a first set of the conductive structures, a conductive clip directly connected to one of the conductive structures of the first layer and to a second side of the semiconductor die, and a package structure that encloses the semiconductor die and a portion of the conductive clip.

### BACKGROUND

Electronic circuits are susceptible to reduced efficiency and degraded operation caused by parasitic inductance, particularly at higher operating frequencies. High frequency devices are also subject to reduced efficiency at elevated operating temperatures. Thermal limitations of conventional device packages with only bottom side cooling through a printed circuit board (PCB) prevent reducing the device size and inhibit increasing the device power density. In addition, good electrical performance of switching circuits is enhanced by grounding the backside of a semiconductor die that includes one or more power circuit switching transistors. Current packaging solutions with wire bonded dies and lead frames suffer from high parasitic inductance and cannot provide topside cooling or backside die grounding. Lidded embedded die packages have an inverted die or flip chip with a lid on the top side for thermal dissipation, but do not provide a top side ground connection. Other flip chip approaches do not implement a ground connection to the die backside. Further packages having direct plated copper layers on embedded dies with a redistribution layer (RDL) are expensive.

### SUMMARY

Packaged electronic devices are described with an inverted die and a conductive clip attached to a multilayer substrate, as well as a package structure that encloses the semiconductor die and a portion of the conductive clip. Described examples provide a cost effective electronic device packaging solution with good die heat dissipation and electrical performance. A described example packaged electronic device includes a multilayer substrate with a first layer having first conductive structures, and a second layer with second conductive structures. The example device also includes a semiconductor die with an electronic component. The die includes conductive features that are electrically connected to terminals of the electronic component and are directly connected to corresponding conductive structures of the first layer. The example device also includes a conductive clip directly connected to one of the first conductive structures of the first layer. The clip is directly connected to a side of the semiconductor die. The example device also includes a package structure that encloses the semiconductor die and a portion of the conductive clip.

In certain examples, the multilayer substrate includes a third layer or multiple intermediate layers between the first layer and the second layer, with conductive vias that individually connect some of the first conductive structures with some of the second conductive structures. The third layer also includes an insulator structure that separates the vias from one another. In one example, the multilayer substrate is a laminate structure where the insulator structure includes a laminate buildup material. In another example, the multilayer substrate is a ceramic or insulated metal substrate (IMS), in which the insulator structure includes a ceramic material. In one example, the package structure includes a molded material that encloses the semiconductor die and a portion of the conductive clip. The molded material in one example separates at least some of the first conductive structures from one another in the first layer, and separates at least some of the second conductive structures from one another in the second layer. In one example, the conductive clip is soldered to one of the first conductive structures of the first layer, and the clip is soldered or epoxied to the semiconductor die. In one example, the device also includes a second semiconductor die, with second conductive features that are directly connected to corresponding ones of the conductive structures of the first layer.

A method is described for fabricating an electronic device. The method includes soldering conductive features of a first side of a semiconductor die to a first set of conductive structures of a first layer of a multilayer substrate, and attaching a conductive clip to the multilayer substrate and to the semiconductor die. In one example, attaching the conductive clip includes soldering a first portion of the conductive clip to a further conductive structure of the first side of the first layer, and attaching a second portion of the conductive clip to a second side of the semiconductor die. In one example, the second portion of the conductive clip is soldered to the second side of the semiconductor die. In another example, the second portion of the conductive clip is epoxied to the second side of the semiconductor die. The method further includes enclosing the semiconductor die and a portion of the conductive clip in a package structure. In one example, the method also includes soldering a second semiconductor die to a second set of the conductive structures before attaching the conductive clip to the multilayer substrate and to the semiconductor die.

### BRIEF DESCRIPTION OF THE DRAWINGS

FIG. 1 is a sectional side elevation view of a flip chip packaged electronic device with a multilayer laminate substrate including a multilayer laminate structure, and an exposed clip.

FIG. 2 is a top elevation view of the packaged electronic device taken along line 2-2 in FIG. 1.

FIG. 3 is a sectional top elevation view of the packaged electronic device taken along line 3-3 in FIG. 1.

FIG. 4 is a bottom elevation view of the packaged electronic device taken along line 4-4 in FIG. 1.

FIG. 5 is a flow diagram of a method of fabricating a packaged electronic device.

FIGS. 6-12 are sectional side elevation views of the packaged electronic device of FIGS. 1-4 undergoing fabrication according to the method of FIG. 5.

FIG. 13 is a sectional side elevation view of another example flip chip packaged electronic device with a multilayer ceramic or insulated metal substrate, and an exposed clip.

### DETAILED DESCRIPTION

In the drawings, like reference numerals refer to like elements throughout, and the various features are not necessarily drawn to scale. In the following discussion and in the claims, the terms “including”, “includes”, “having”, “has”, “with”, or variants thereof are intended to be inclusive in a manner similar to the term “comprising”, and thus should be interpreted to mean “including, but not limited to . . . ” Also, the term “couple” or “couples” is intended to include indirect or direct electrical or mechanical connection or combinations thereof. For example, if a first device couples to or is coupled with a second device, that connection may be through a direct electrical connection, or through an indirect electrical connection via one or more intervening devices and connections.

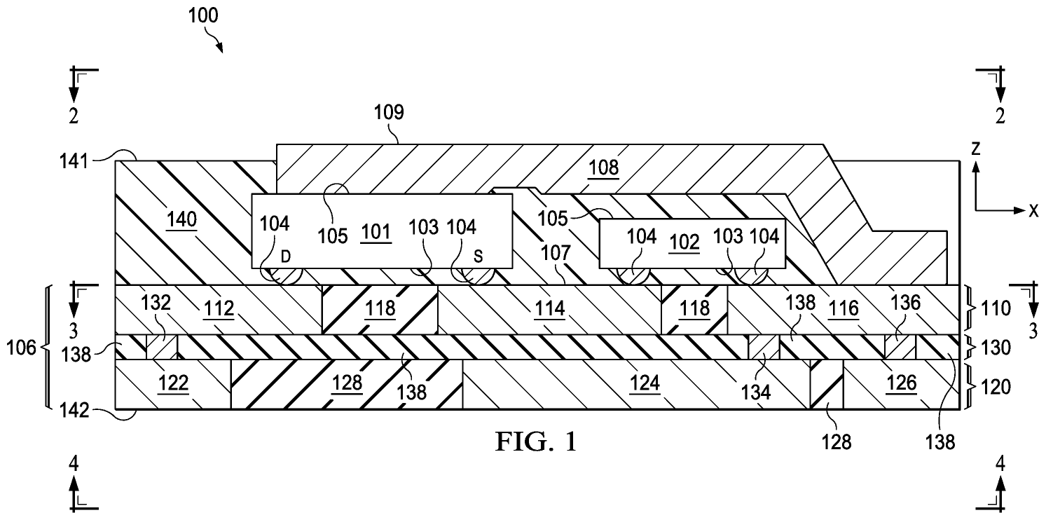

FIGS. 1-4 show an example packaged electronic device 100 with a first semiconductor die 101 and a second semiconductor die 102. Although the example device 100 includes multiple semiconductor dies 101 and 102, other examples can include a single semiconductor die, or more than two semiconductor dies. In the illustrated example, both semiconductor dies include a lower first surface 103 with conductive features 104 that are flip chip soldered to conductive structures of a multilayer substrate 106. The example conductive features 104 extend outward (e.g., downward) from the lower first side 103 of the semiconductor dies 101 and 102. Any suitable conductive features 104 can be used which can be soldered or otherwise directly connected to copper pads or other conductive structures of the multilayer substrate 106. In one example, the conductive features 104 of the dies 101 and 102 are solder bumps. In another example, the conductive features 104 are copper pillars.

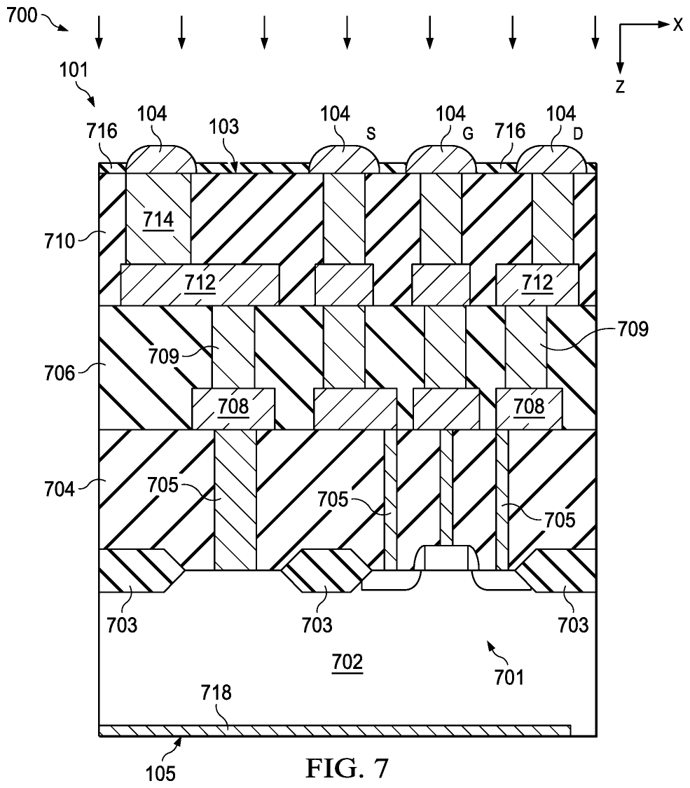

In one example, the dies 101 and 102 are fabricated with one or more electronic components (e.g., transistors, resistors, capacitors, diodes, etc.), as discussed further below in connection with FIG. 7. In one example, the first die 101 includes a power transistor, such as a high electron mobility transistor (HEMT), for example, a silicon carbide (SiC) transistor or a gallium nitride (GaN) transistor. The example dies 101 and 102 also include one or more metallization layers with an upper side 103 having copper pillars, solder bumps or other conductive features 104 that extend outward from the upper side 103. At least some of the conductive features 104 are electrically connected via the metallization layer or layers to terminals of the electronic component or components within the dies 101 and 102. In this example, the dies 101 and 102 are inverted or ‘flipped’ to solder the conductive features 104 of the first side 103 downward onto the conductive structures of the multilayer substrate 106 using a flip chip attachment process. The inverted positioning of the dies 101 and 102 leaves a second side 105 of the dies facing upward (e.g., along the positive Z direction) in FIG. 1. The flip chip process directly attaches the dies 101 and 102 to a first (e.g., upper) side 107 of the multilayer substrate 106. The direct electrical connection of the conductive features 104 to the conductive structures of the multilayer substrate 106 advantageously mitigates or avoids parasitic inductances associated with wire bonding or other interconnection techniques.

The device 100 also includes a conductive clip 108. The clip 108 can be any suitable conductive material, such as aluminum, copper, etc. The conductive clip 108 is directly connected to one or more conductive structures on the first side 107 of the multilayer substrate 106. In one example a lower first portion of the clip 108 is soldered directly to one or more conductive structures on the first side 107 of the multilayer substrate 106. In addition, the conductive clip 108 is directly connected to the second side 105 of the first semiconductor die 101. In one example, the upper second portion of the conductive clip 108 is soldered directly to a conductive feature on the second side 105 of the first semiconductor die 101. In another example, the second portion of the conductive clip 108 is epoxied to a portion of the second side 105 of the first semiconductor die 101. In one implementation, the conductive clip 108 is soldered to a grounded conductive structure on the first side 107 of the multilayer substrate 106, for example, a ground connection.

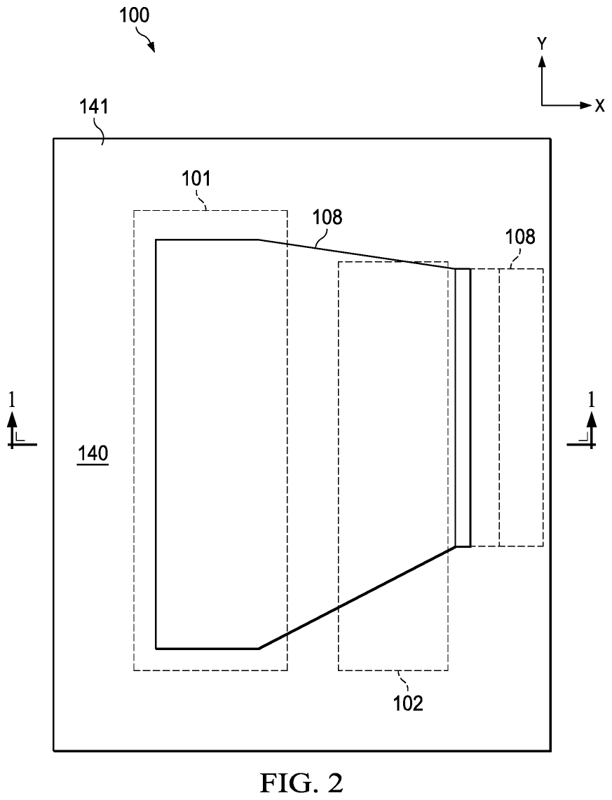

Referring also to FIGS. 2-4, FIG. 2 shows a top view of the packaged electronic device 100 taken along line 2-2 in FIG. 1. The conductive clip 108 in FIGS. 1 and 2 extends over, and is spaced apart from, a portion of the second semiconductor die 102. The clip 108 in this example provides a ground shield to protect the first and/or second semiconductor dies 101 and/or 102 from electromagnetic interference (EMI) during operation of the device 100, whether soldered or epoxied to the second side 105 of the first semiconductor die 101. In the example of FIG. 1, the conductive clip 108 includes an upper first side 109 that is exposed to the exterior of the packaged electronic device 100. The clip 108 also functions to facilitate heat dissipation from the attached first semiconductor die 101. In use, a heat sink (not shown) can be soldered, epoxied, or otherwise attached to the exposed first side 109 of the conductive clip 108 to further facilitate heat dissipation.

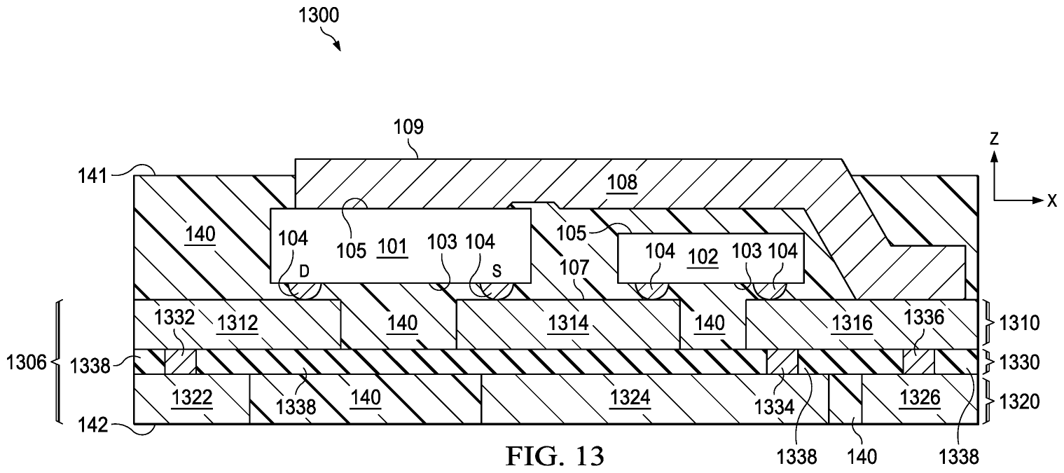

The example multilayer substrate 106 in FIG. 1 is a multilayer laminate substrate structure. In another implementation (e.g., FIG. 13 below) the multilayer substrate 106 is a ceramic substrate or an insulated metal substrate (IMS). As shown in FIG. 1, the multilayer laminate substrate 106 includes a first layer 110 at the first (e.g., top) side 107, as well as a bottom second layer 120. The multilayer substrate 106 facilitates signal routing and interconnection locations not possible or impractical with lead frames. The example of FIG. 1 also includes an intermediate third layer 130. The first layer 110 includes first plurality of conductive structures 112, 114 and 116 that extend through the first layer 110 to the first side 107 of the multilayer substrate 106. The conductive structures 112, 114 and 116 are laterally spaced apart from one another (e.g., along the X direction in FIG. 1). In addition, the conductive structures 112, 114 and 116 are separated from one another by a first insulation structure 118.

In the example of FIG. 1, a first conductive structure 112 is soldered to a first conductive feature 104 of the semiconductor die 101. In one example, the first semiconductor die 101 includes a transistor component (e.g., transistor 701 in FIG. 7 below), and the second semiconductor die 102 includes transistor driver circuitry (not shown). In this example, the first conductive feature 104 of the semiconductor die 101 is electrically connected to a drain terminal of the transistor (labeled “D” in FIG. 1). A second conductive structure 114 of the first layer 110 is soldered to a second conductive feature 104 of the semiconductor die 101, and a third conductive structure 116 is soldered to a first portion of the conductive clip 108. In the example of FIG. 1, the second conductive feature 104 of the semiconductor die 101 is electrically connected to a source terminal of the transistor (labeled “S” in FIG. 1). In one example, the driver circuit die 102 connects the source terminal of the transistor die 101 to a circuit ground node or other reference voltage node, and a corresponding ground conductive feature 104 of the second die 102 is soldered to the third conductive structure 116.

In the illustrated example, the first portion of the conductive clip 108 is soldered directly to the third conductive structure 116 on the first side 107 of the multilayer substrate 106. In this manner, the conductive clip 108 is directly electrically connected to the circuit ground, and provides a grounded shield to the dies 101 and 102. In one example, moreover, the first semiconductor die 101 includes an upper body contact (not shown in FIG. 1, illustrated in FIG. 7 below) on the second (e.g., upper) side 105, and the body contact is soldered to the second portion of the conductive clip 108. In this implementation, the conductive clip 108 provides a soldered direct electrical ground connection to the body of the semiconductor die 101.

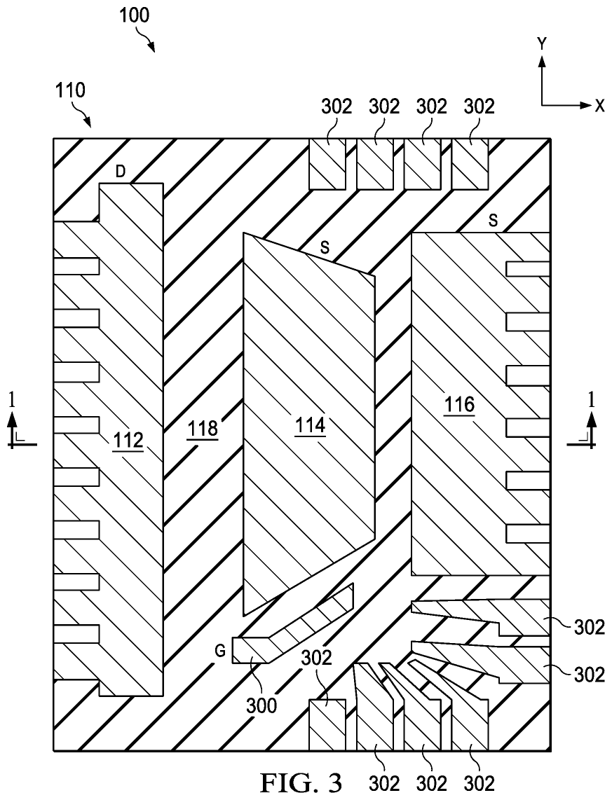

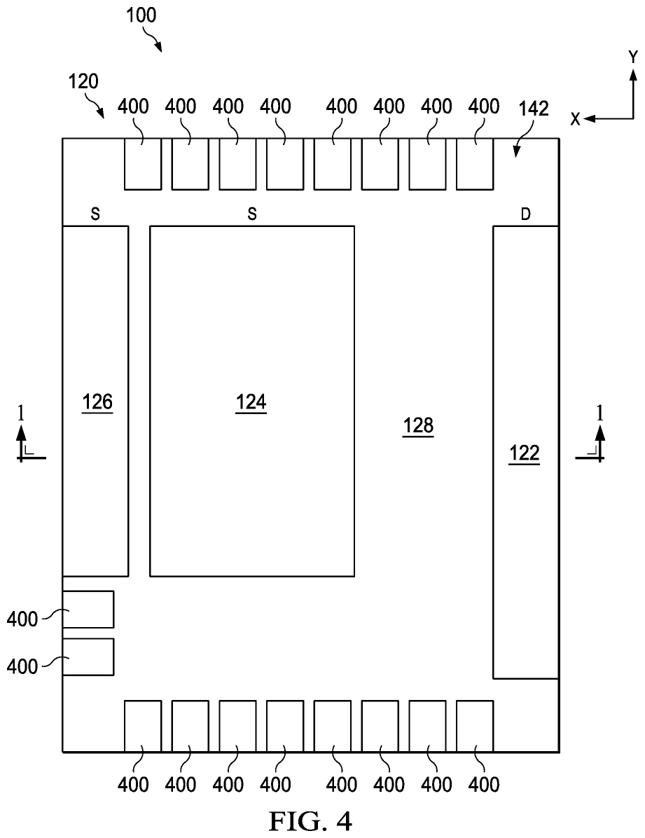

FIG. 3 is a sectional top view taken along line 3-3 through the first layer 110, and FIG. 4 is a bottom view showing features of the second (e.g., bottom) layer 120 of the packaged electronic device taken along line 4-4 in FIG. 1. The second layer 120 includes a second plurality of conductive structures 122, 124, 126 and 128. The conductive structures 122, 124, 126 and 128 extend through the second layer 120 of the multilayer substrate 106. The second plurality of conductive structures includes a fourth conductive structure 122, a fifth conductive structure 124, and a sixth conductive structure 126. The fourth conductive structure 122 is electrically connected through the third layer 130 of the multilayer substrate 106 to the first conductive structure 112 of the first layer 110. The fifth conductive structure 124 is electrically connected through the third layer 130 to the third conductive structure 116. The illustrated example second layer 120 also includes the sixth conductive structure 126. The sixth conductive structure 126 is electrically connected through the third layer 130 to the third conductive structure 116.

The third layer 130 includes conductive vias 132, 134 and 136 that extend between the first layer 110 and the second layer 120. The vias 132, 134 and 136 can be any suitable conductive material, such as aluminum, copper, etc. The third layer 130 also includes an insulator structure 138 that separates at least some of the conductive vias 132, 134 and/or 136 from one another. In the laminate substrate example of FIGS. 1-4, the insulator structure 138 of the third layer 130 includes a laminate buildup material 138. In the illustrated example, the insulator structures 118, 128 and 138 of the multilayer substrate 106 are each constructed of laminate buildup material. The buildup material in one example begins as sheets that are pressed or otherwise installed into gaps between the conductive structures or vias of the individual layers 110, 120 and 130. This technique is referred to as dry film lamination. In one example, the insulator structures 118, 128 and 138 and the constituent buildup material sheets are or include an organic material.

The packaged electronic device 100 also includes a package structure 140. The package structure 140 can be any suitable package material to enclose all or portions of the components of the device 100, for example, a molded plastic material, a ceramic material, etc. The package material includes a first (e.g., top) side 141. In the example of FIG. 1, the first side 109 of the conductive clip 108 extends vertically past the first side 141 of the package material 140, allowing heat dissipation from the clip 108 and/or allowing attachment of an external heat sink (not shown) to the device 100. The packaged electronic device 100 also includes a second (e.g., bottom) side 142, with exposed portions of the second plurality of conductive structures 122, 124 and 126 shown in FIG. 1. In use, the exposed conductive structures 122, 124 and 126 of the second side 142 of the packaged electronic device 100 are soldered to a host PCB (not shown) to provide electrical connection from circuitry of the host PCB with the circuit formed by the semiconductor dies 101, 102 and the multilayer substrate 106.

The conductive vias 132, 134 and 136 of the third layer 130 individually connect some of the conductive structures 112, 114 and 116 of the first layer 110 with some of the conductive structures 122, 124 and 126 of the second layer 120. In the example of FIG. 1, a first via 132 directly electrically connects the transistor drain of the first semiconductor die 101, through the first conductive structure 112 of the first layer 110, to the fourth conductive structure 122 of the second layer 120. In this example, the fourth conductive structure 122 provides a drain connection at the bottom side 142 of the packaged electronic device 100 that can be soldered to a PCB (not shown). The second via 134 of the third layer 130 electrically connects the ground node from the third conductive structure 116 to the fifth conductive structure 124 of the second layer 120. In addition, the third via 136 of the third layer 130 electrically connects the ground node from the third conductive structure 116 to the sixth conductive structure 126. The conductive structures 124 and 126 provide ground or source connections at the bottom side 142 of the device 100, which can be soldered to a user PCB.

The sectional side view of the device 100 in FIG. 1 is taken along lines 1-1 in FIGS. 2-4, and does not show all the features of the example multilayer substrate 106. FIG. 3 shows an example top sectional view of the first layer 110, which includes the first conductive structure 112 (labeled “D”), portions of which extend to the lateral edge of the first layer 110. The example second conductive structure 114 of the first layer 110 is wider on the left side than on the right side to provide a source connection (labeled S) between the first and second semiconductor dies 101 and 102 (FIG. 1). The first layer 110 also includes a conductive structure 300 (labeled “G”) that provides a gate control signal interconnection between the driver circuit die 102 and the gate terminal of the transistor in the first semiconductor die 101. The transistor gate terminal in this example is connected through a corresponding conductive feature (not shown) of the first semiconductor die 101 that is soldered to a top surface of the conductive structure 300. The second semiconductor die 102 in this example includes a gate control signal output with a corresponding conductive feature (not shown) that is soldered to a second end of the conductive structure 300. The conductive structure 300 allows the driver die 102 to provide a gate control signal to operate the transistor of the first semiconductor die 101. FIG. 3 also illustrates the third conductive structure 116 that provides a ground node connection for the conductive clip 108. In addition, the first layer 110 includes further conductive structures 302 to facilitate connection to, and routing of signals to or from, other circuitry in the driver die 102.

FIG. 4 shows a bottom view of the second layer 120 of the packaged electronic device 100. The second layer 120 includes the fourth conductive structure 122 that provides the drain connection at the bottom side 142 of the packaged electronic device 100. The bottom side of the second layer 120 also includes the fifth conductive structure 124 (e.g., ground node connection), and a sixth conductive structure 126 (e.g., a further ground node connection). The example second layer 120 in FIG. 4 also includes exposed portions of further conductive structures 400.

The example packaged electronic device 100 advantageously combines a multilayer substrate 106 with one or more flip chip soldered dies 101 and 102, and the conductive clip 108 which solves a variety of thermal and electrical shortcomings of previous packaging configurations. The various features of the example device 100 can be used in connection with GaN, SiC or other HEMT transistor circuits for improved high-frequency operation in combination with advantages associated with high power density, and low cost. In certain implementations, the device 100 facilitates packaging of a flip chip GaN die 101 and driver circuitry 102 without parasitic inductances previously associated with bond wires.

The described device 100 also provides the exposed conductive clip 108 attached to the backside of the die 101 for improved heat dissipation through topside cooling along with a grounded clip attachment to the backside 105 of the first die 101 for good electrical performance. This represents a significant improvement over other solutions that do not implement a ground connection to a die backside in a flip chip package. The device 100 also provides significant cost advantages compared with embedded die packaging solutions with redistribution layer features. In addition, the use of the multilayer substrate 106 advantageously facilitates complex interconnection routing capabilities compared with lead frame techniques. In addition, the example multilayer laminate structure 106 facilitates low electrical parasitics for further improvement in high-frequency circuit applications. In addition, the example device 100 provides good thermal heat dissipation in combination with a grounded backside connection, which was not possible using lidded CCC packages. As discussed further below in connection with FIG. 13, the multilayer substrate 106 can be implemented using a variety of different constructions, including a multilayer laminate substrate (e.g., FIGS. 1-4), a ceramic substrate, or an insulated metal substrate (e.g., IMS, FIG. 13).

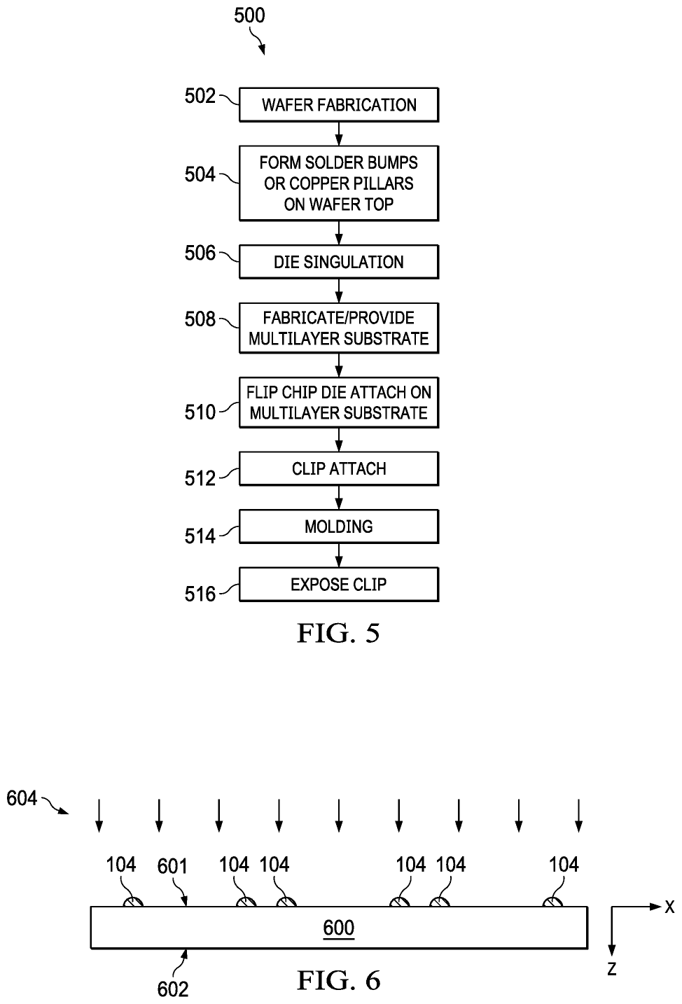

Referring now to FIGS. 5-12, FIG. 5 shows an example method 500 to fabricate a packaged electronic device. In one example, the method 500 can be used to fabricate the example packaged electronic device 100 of FIGS. 1-4 described above. The method 500 can be used to fabricate other packaged electronic devices, such as the example device described below in connection with FIG. 13. The method 500 is described below in connection with fabrication of the example device 100, and FIGS. 6-12 show the packaged electronic device 100 undergoing fabrication according to the method 500.

The example method 500 includes wafer fabrication at 502, and formation of solder bumps or copper pillars on the wafer top at 504. FIG. 6 shows one example, in which a process 604 is performed to fabricate a wafer 600 including multiple perspective die areas, each having one or more corresponding solder bump or copper pillar conductive features 104 that extend outward from a first side 601 of the wafer 600. The example wafer 600 also includes a backside 602.

The method 500 also includes die separation or singulation at 506 in FIG. 5. The dies 600 in FIG. 6 can be separated into multiple semiconductor dies (e.g., the first die 101 in FIG. 1) using any suitable saw cutting, laser cutting, etching, or other separation processing (not shown). FIG. 7 shows a portion of the example first die 100 separated from the wafer 600 of FIG. 6 and undergoing a process 700 that forms conductive features 104 (e.g., copper pillars or solder bumps) on the first side 103 of the separated die 101.

The example first die 101 in FIG. 7 includes a transistor component 701 formed on and/or in a semiconductor substrate 702 (e.g., silicon, gallium nitride, silicon carbide, silicon-on-insulator (SOI), etc.). Although the example first die 101 includes a single transistor component 701, other implementations include integrated circuits having multiple electronic components formed in the die 101. The processed die 101 in this example includes multiple conductive features 104 that are individually electrically connected to corresponding terminals (source “S”, drain “D”, gate “G”, and a back gate contact) of the transistor component 701. The conductive features 104 are aluminum, copper, solder material, or other conductive material suitable for subsequent soldering to corresponding ones of the conductive structures 112, 114 of the first layer 110 of the multilayer substrate 106 (e.g., FIG. 1).

The example die 101 also includes isolation structures 703 disposed on select portions of an upper surface or side of the substrate 702. The isolation structures 703 can be shallow trench isolation (STI) features or field oxide (FOX) structures in some examples. The example die 101 also includes a multilayer metallization structure disposed above the substrate 702. The metallization structure includes a first dielectric structure layer 704 formed over the substrate 702, as well as a multilevel upper metallization structure 706, 710. In one example, the first dielectric structure layer 704 is a pre-metal dielectric (PMD) layer disposed over the transistor 701 and the upper surface of the substrate 702. In one example, the first dielectric structure layer 704 includes silicon dioxide (SiO₂) deposited over the transistor 701, the substrate 702 and the isolation structures 703.

The metallization structure includes tungsten plugs or contacts 705 that extend from various terminals of the transistor 701 through the PMD layer 704, as well as overlying dielectric layers 706 and 710, referred to herein as interlayer or interlevel dielectric (ILD) layers. Different numbers of layers can be used in different implementations. In one example, the first ILD layer 706 and the final ILD layer 710 are formed of silicon dioxide (SiO₂) or other suitable dielectric material. In certain implementations, the individual layers of the multi-layer upper metallization structure are formed in two stages, including an intra-metal dielectric (IMD, not shown) sub layer and an ILD sublayer overlying the IMD sub layer. The individual IMD and ILD sublayers can be formed of any suitable dielectric material or materials, such as SiO₂-based dielectric materials.

The first ILD layer 706 and the upper ILD layer 710 include conductive metallization interconnect structures 708 and 712, such as aluminum formed on the top surface of the underlying layer, as well as vias 709, such as tungsten, providing electrical connection from the metallization features 708, 712 of an individual layer to an overlying metallization layer. The substrate 702, the electronic components 701, the first dielectric structure layer 704 and the upper metallization structure 706, 710 form a die 101 with an upper side or surface 103. The top metallization layer 710 includes example conductive features 714, such as upper most aluminum vias. The conductive features 714 include a side or surface at the upper side 103 of the die 101 at the top of the uppermost metallization layer 710. Any number of conductive features 714 may be provided. One or more of the conductive features 714 are electrically coupled with the transistor 701 through the metallization structure of the die 101.

The upper ILD dielectric layer 710 in one example is covered by one or more passivation layers 716 (e.g., protective overcoat (PO) and/or passivation layers), for example, silicon nitride (SiN), silicon oxynitride (SiOₓN_{y}), or silicon dioxide (SiO₂). In one example, the passivation layer or layers 716 include one or more openings that expose a portion of the conductive features 714 to allow electrical connection of the features 714 to corresponding contacts or conductive features 104. The conductive features 104 extend outward (e.g., upward along the negative “Z” direction in FIG. 7) from the first (e.g., upper) side 103 of the metallization structure. The conductive features 104 in one example include a conductive seed layer, such as copper that extends outward from the upper side 103 of the metallization structure. In one example, the conductive features 104 include conductive pillars. In another example, the conductive features 104 are solder bumps. The example die 101 in FIG. 7 also includes a bottom conductive feature 718 (not shown in FIG. 1) formed on the second side 105 of the die 101.

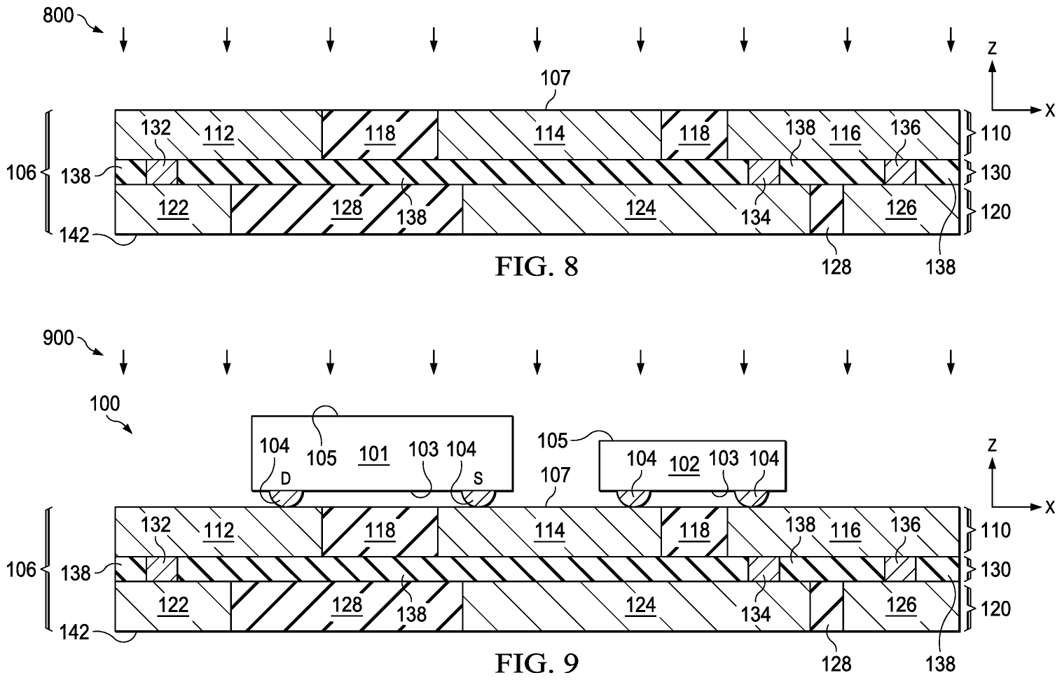

The method 500 continues at 508 in FIG. 5 with fabrication or provision of a multilayer substrate (e.g., 106 in FIG. 1 above). In one example, the multilayer substrate 106 is a laminate substrate (e.g., FIGS. 1-4). In another example, the multilayer substrate is fabricated at 508 as a ceramic substrate or an insulated metal substrate (e.g., FIG. 13 below). FIG. 8 shows one example, in which a lamination process 800 is performed that creates the multilayer laminate substrate 106 illustrated and described above in connection with FIGS. 1-4.

The method 500 continues at 510 in FIG. 5 with attaching the die or dies on the multilayer substrate. FIG. 9 shows one example, in which a flip chip die attach soldering process 900 is performed that solders the conductive features 104 of the first side 103 of the semiconductor die 101 to a first set of conductive structures 112, 114 and 116 of the first layer 110 of the example multilayer laminate substrate 106. In this example, the first and second dies 101 and 102 are concurrently or separately inverted and positioned on the first side 107 of the multilayer laminate substrate 106, and the device 100 is heated to reflow the solder material of the solder bumps 104 in order to form a solder joint with the conductive structures 112, 114 and 116.

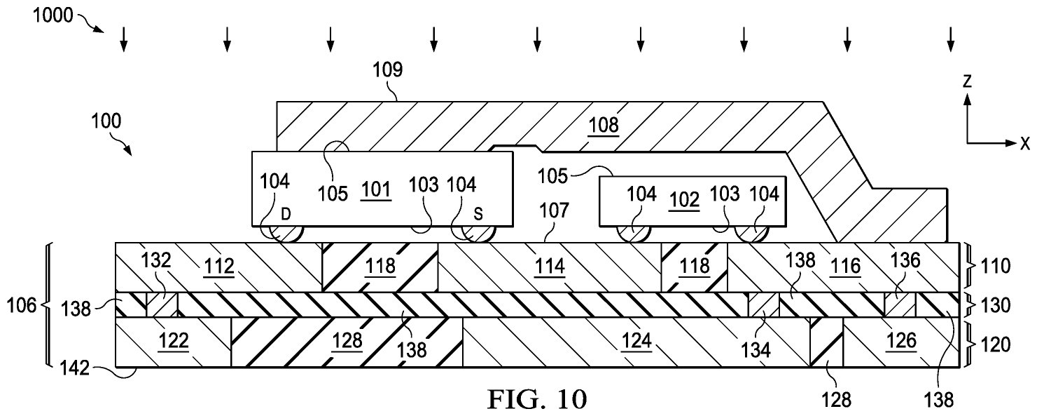

At 512 in FIG. 5, the method further includes attaching the conductive clip to the multilayer substrate and to the semiconductor die. FIG. 10 shows one example in which an attachment process 1000 is performed that solders the lower first portion of the conductive clip 108 to the third conductive structure 116. In one example, the attachment process 1000 also solders the upper second portion of the conductive clip 108 to the second side 105 of the first semiconductor die 101 (e.g., to the bottom conductive feature 718 in FIG. 7). In this example, the soldered attachment of the conductive clip 108 to the second side 105 of the first semiconductor die 101 provides an electrical body connection to the ground node at the conductive structure 116 through the conductive clip 108. In another example, the clip attachment process 1000 epoxies the second portion of the conductive clip to the second side 105 of the first semiconductor die 101. In both examples, the clip operates as a grounded shield to protect the circuitry of the first and second semiconductor dies 101 and 102. In addition, the attachment of the clip 108 to the second side 105 of the first semiconductor die 101 provides a thermal path to dissipate heat from the die 101. As previously mentioned, an end user can attach a heat sink to the top side 109 of the conductive clip 108 to further facilitate heat dissipation.

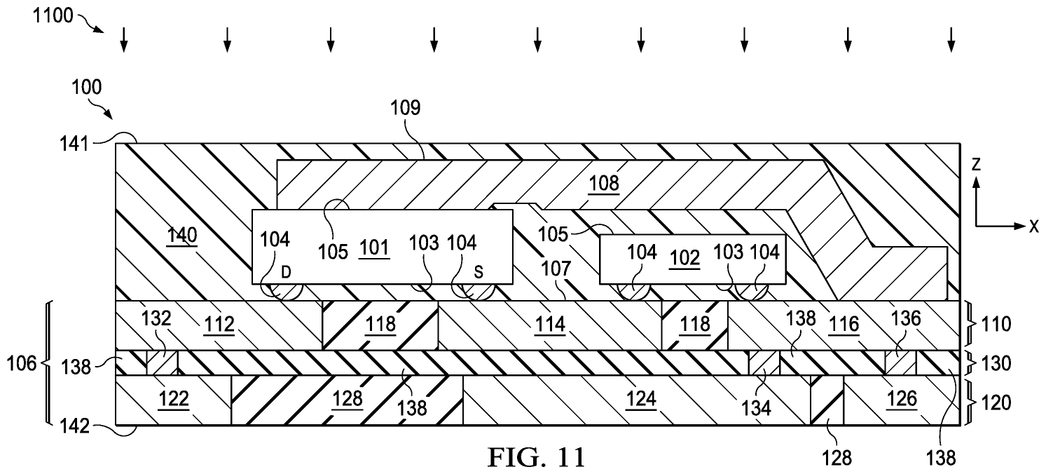

At 514 in FIG. 5, the method 500 further includes enclosing the semiconductor dies 101 and 102 and a portion of the conductive clip 108 in a package structure. FIG. 11 shows one example, in which a molding process 1100 is performed that encloses the upper structure of the device 100 in a plastic molded material 140. In this example, the molding process 1100 initially provides the molded package structure 140 with an upper or top surface 141 that is above the top side 109 of the conductive clip 108.

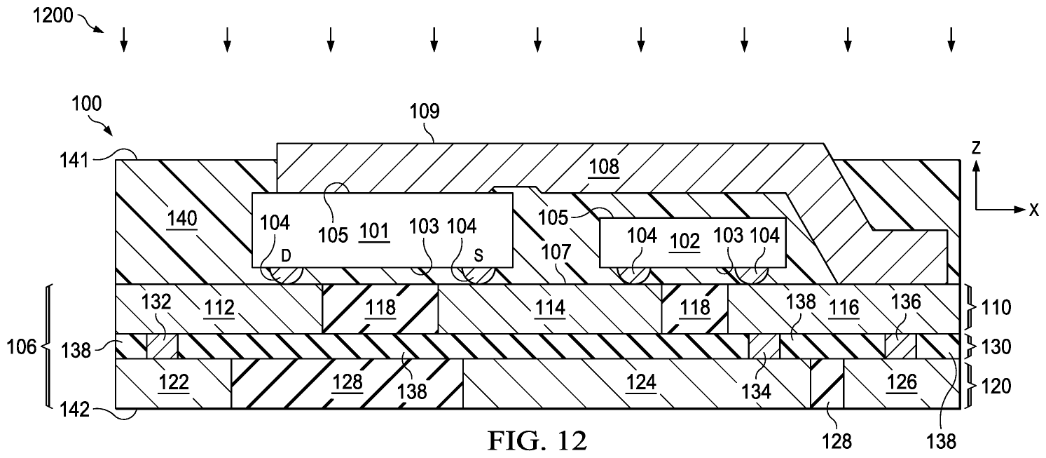

At 516 in FIG. 5, the example method 500 further includes exposing a portion of the clip 108. FIG. 12 shows one example in which a material removal process 1200 is performed that removes a portion of the top surface of the molded package structure 140 to expose an upper portion of the top side 109 of the conductive clip 108.

In another possible example, a ceramic package structure (not shown) can be used to enclose all or portions of the semiconductor dies 101, 102 and at least a portion of the conductive clip 108.

FIG. 13 shows another example packaged electronic device 1300 that includes a flip chip package with a multilayer ceramic or insulated metal substrate 1306, and an exposed clip. The device 1300 includes the first and second semiconductor dies 101 and 102 and the conductive clip 108 as described above. In this example, the multilayer substrate 1306 includes a first side 107, a second side 142, a first layer 1310, a second layer 1320 and a third layer 1330. The first layer 1310 includes a first plurality of conductive structures 1312, 1314 and 1316 that extend through the first layer 1310 to the first side 107, and the second layer 1320 includes a second plurality of conductive structures 1322, 1324 and 1326 that extend through the second layer 1320 to the second side 142. The third layer 1330 includes conductive vias 1332, 1334 and 1336 that extend through the third layer 1330 between the first and second layers 1310 and 1320, respectively. The third layer 1300 also includes an insulator structure 1338 that separates the vias 1332, 1334 and 1336 from one another. The insulator structure 1338 in this example includes a ceramic material 1338.

The conductive structures 1312, 1314 and 1316 of the first layer 1300 in one example are created as a direct bonded copper (DBC) substrate, and the ceramic insulator structure 1338 of the third layer 1300 is a dielectric material, with the vias 1332, 1334, and 1336 providing electrical interconnection between the first and second layers 1310 and 1320. In this example, moreover, the package structure 140 includes a molded material that encloses the semiconductor die 101 and the upper portion of the conductive clip 108. The molded material 140 in this example also separates at least some of the first plurality of conductive structures 1312, 1314, and/or 1316 from one another in the first layer 1310. In addition, the molded material 140 in FIG. 13 separates at least some of the second plurality of conductive structures 1322, 1324, and 1326 in the second layer 1320 at the bottom of the package electronic device 1300.

Described packaging solutions facilitate good thermal and electrical performances with a simple and low cost implementation that allows complex signal routing beyond the capabilities of lead frame designs. The exposed clip facilitates heat dissipation to the ambient or an attached heat sink, and allows connection to a ground or other reference voltage. The multilayer substrate avoids the parasitic inductance problems of wire bonded packages without the added cost and complexity of embedded die packaging. In addition, the multilayer substrate enables more complicated routing than lead frames. Example applications include power circuits with HEMT devices (e.g., GaN or SiC transistors, etc.), and multiple dies can be accommodated in a single packaged device.

Modifications are possible in the described embodiments, and other embodiments are possible, within the scope of the claims.

1. A packaged electronic device, comprising:
a multilayer substrate, including: a first side, a second side, a first layer having a first plurality of conductive structures that extend through the first layer to the first side, and a second layer having a second plurality of conductive structures that extend through the second layer to the second side;
a semiconductor die, including: an electronic component, and a plurality of conductive features electrically connected to terminals of the electronic component, the conductive features extending outward from a first side of the semiconductor die, and the conductive features directly connected to corresponding ones of the first plurality of conductive structures of the first layer;
a conductive clip directly connected to one of the first plurality of conductive structures of the first layer, and directly connected to a second side of the semiconductor die; and
a package structure that encloses the semiconductor die and a portion of the conductive clip.

2. The packaged electronic device of claim 1,
wherein the first plurality of conductive structures includes:
a first conductive structure soldered to a first conductive feature of the semiconductor die,
a second conductive structure soldered to a second conductive feature of the semiconductor die, and
a third conductive structure soldered to a first portion of the conductive dip; and
wherein the second plurality of conductive structures includes:
a fourth conductive structure electrically connected in the multilayer substrate to the first conductive structure, and
a fifth conductive structure electrically connected in the multilayer substrate to the third conductive structure.

3. The packaged electronic device of claim 2,
wherein the electronic component of the semiconductor die is a transistor;
wherein the first conductive feature of the semiconductor die is electrically connected to a drain terminal of the transistor; and
wherein the second conductive feature of the semiconductor die is electrically connected to a source terminal of the transistor.

4. The packaged electronic device of claim 2, wherein the second plurality of conductive structures further includes a sixth conductive structure electrically connected in the multilayer substrate to the third conductive structure.

5. The packaged electronic device of claim 2,
wherein the multilayer substrate further includes a third layer disposed between the first layer and the second layer, the third layer including:
conductive vias that extend between the first layer and the second layer to individually connect some of the first plurality of conductive structures with some of the second plurality of conductive structures, and
an insulator structure that separates at least some of the conductive vias from one another.

6. The packaged electronic device of claim 5, wherein the insulator structure of the third layer includes a laminate buildup material.

7. The packaged electronic device of claim 5, wherein the insulator structure of the third layer includes a ceramic material.

8. The packaged electronic device of claim 7,
wherein the package structure includes a molded material that encloses the semiconductor die and the portion of the conductive clip;
wherein the molded material of the package structure separates at least some of the first plurality of conductive structures from one another in the first layer; and
wherein the molded material of the package structure separates at least some of the second plurality of conductive structures in the second layer.

9. The packaged electronic device of claim 5, wherein the conductive clip is soldered to one of the first plurality of conductive structures of the first layer, and wherein the conductive clip is soldered to the second side of the semiconductor die.

10. The packaged electronic device of claim 2,
wherein the multilayer substrate further includes a third layer disposed between the first layer and the second layer, the third layer including:
conductive vias that extend between the first layer and the second layer, and
an insulator structure that separates at least some of the conductive vias from one another.

11. The packaged electronic device of claim 10, wherein the insulator structure of the third layer includes a laminate buildup material.

12. The packaged electronic device of claim 10, wherein the insulator structure of the third layer includes a ceramic material.

13. The packaged electronic device of claim 12,
wherein the package structure includes a molded material that encloses the semiconductor die and the portion of the conductive clip;
wherein the molded material of the package structure separates at least some of the first plurality of conductive structures from one another in the first layer; and
wherein the molded material of the package structure separates at least some of the second plurality of conductive structures in the second layer.

14. The packaged electronic device of claim 1, wherein the conductive clip is soldered to one of the first plurality of conductive structures of the first layer, and wherein the conductive clip is soldered to the second side of the semiconductor die.

15. The packaged electronic device of claim 1, further comprising a second semiconductor die, including second plurality of conductive features directly connected to corresponding ones of the first plurality of conductive structures of the first layer.

16. An electronic device, comprising:
a multilayer substrate, including:
a first layer, including a first plurality of conductive structures,
a second layer, including a second plurality of conductive structures, and
a third layer disposed between the first layer and the second layer, the third layer including: conductive vias that extend between the first layer and the second layer to individually connect some of the first plurality of conductive structures with some of the second plurality of conductive structures, and an insulator structure that separates at least some of the conductive vias from one another;
a semiconductor die, including: an electronic component, and a plurality of conductive features electrically connected to terminals of the electronic component, the conductive features soldered to corresponding ones of the first plurality of conductive structures of the first layer; and
a conductive clip directly soldered to one of the first plurality of conductive structures of the first layer, and directly connected to the semiconductor die.

17. The packaged electronic device of claim 16, wherein the insulator structure of the third layer includes a laminate buildup material.

18. The packaged electronic device of claim 16, wherein the insulator structure of the third layer includes a ceramic material.

19-20. (canceled)

21. A packaged electronic device, comprising:
conductive features of a first side of a semiconductor die soldered to a first set of conductive structures of a first layer of a multilayer substrate;
a conductive clip attached to the multilayer substrate and to the semiconductor die, including;
a first portion of a conductive clip soldered to a further conductive structure of the first side of the first layer, and
a second portion of the conductive clip attached to a second side of the semiconductor die; and
a package structure enclosing the semiconductor die and a portion of the conductive clip.

22. The packaged electronic device of claim 21, further comprising:
a second semiconductor die soldered to a second set of the conductive structures.
